(19) United States
(12) Patent Application Publication
(10) Pub. No.: US 2014/0182670 A1
(43) Pub. Date: Jul. 3, 2014

(54) LIGHT TRAPPING AND ANTIREFLECTIVE COATINGS

(71) Applicant: INTERMOLECULAR INC., San Jose, CA (US)

(72) Inventors: Jeroen Van Duren, Palo Alto, CA (US); Scott Jewhurst, Redwood City, CA (US); Nikhil Kalyankar, Mountain View, CA (US)

(73) Assignee: INTERMOLECULAR INC., San Jose, CA (US)

(21) Appl. No.: 13/727,741

(22) Filed: Dec. 27, 2012

(51) Int. Cl. C09D 5/00; H01L 31/0216

(52) U.S. Cl. CPC C09D 5/006; H01L 31/02168
USPC 136/256; 428/144; 427/165

(57) ABSTRACT

Light trapping and antireflection coatings are described, together with methods for preparing the coatings. An exemplary method comprises forming a light trapping coating on a substrate and a conformal antireflection coating on the light trapping coating. The light trapping coating comprises particles embedded in a support matrix having a thickness between about one third and two thirds of the mean particle size. The mean particle size is between about 10 μm and about 500 μm. The index of refraction of the particles and support matrix is substantially the same as the index of refraction of the substrate at wavelengths of interest. The index of refraction of the conformal antireflection coating is approximately equal the square root of the index of refraction of the substrate.

### CROSS REFERENCE TO RELATED APPLICATIONS

This application is related to commonly owned U.S. patent application Ser. No. 12/970,638, filed on Dec. 16, 2010, Ser. No. 13/046,899, filed on Mar. 14, 2011, Ser. No. 13/072,860, filed on Mar. 28, 2011, Ser. No. 13/195,119, filed on Aug. 1, 2011, Ser. No. 13/195,151, filed on Aug. 1, 2011, Ser. No. 13/273,007, filed on Oct. 13, 2011, and Ser. No. 13/723,954, filed on Dec. 21, 2012, each of which is herein incorporated by reference for all purposes.

### FIELD OF THE INVENTION

One or more embodiments of the present invention relate to light trapping, antireflection coatings and methods of forming the coatings.

### BACKGROUND

Antireflection coatings are well known for the purpose of reducing reflectance and increasing transmittance at material boundaries. The coatings can be either single-layer or multi-layer, and generally comprise materials whose index of refraction is intermediate between those of the materials on either side of the boundary. In some applications, textured surfaces are also used (with or without an antireflection coating) to enhance light trapping by reducing specular reflection. When the size scale of the texture is less than the relevant wavelength of light, then the texture can provide enhanced light trapping without reducing the light transmittance. Such textured surfaces with antireflection coatings are especially useful for solar cells, where the goal is to collect as large a fraction of the incident light as possible, although there are many other applications for similar coatings.

For applications such as solar cells, the cost of applying the texture and coatings is very important. Vacuum coating techniques are generally prohibitively expensive. Even dip coating is relatively expensive, because it cannot be implemented in-line on a float-glass production line. The simplest possible coating methods are used whenever practical; for example a “curtain coater” can be used wherein the moving glass is passed under a “curtain” of coating precursor material.

While it is possible to texture the surface of glass prior to coating, for example, by passing softened glass through textured rollers, it is difficult to form textures having sub-micron size scale. Even if such a texture is successfully formed on the surface, a curtain coating method can “level out” the texture resulting in loss of effectiveness.

Some commercial solar cell products are made out of glass that is deliberately patterned by a textured roll during the glass formation process to enhance light trapping and tracking of the sun. This technology is an alternative to sol-gel anti-reflection coatings. However, there are problems with these products. The textured surfaces formed using a textured roller tend to trap dirt resulting in reduced light transmittance. It can also be difficult to control the strength of the glass during rolling, and higher breakage can result, for example, during lamination to solar panels. Furthermore, the textured rollers get dirty easily and impact the texture consistency from plate to plate.

Various materials can be used to make antireflection coatings. For glass-air boundaries, sol-gels are frequently used, because they have a high air fraction and therefore lower index of refraction than the bulk material. Typical glasses have an index of refraction of about 1.5, and air has an index of refraction of 1.0, so sol-gels are a convenient structure that can be used to prepare materials having an intermediate index of refraction. As long as the coating thicknesses are small and the pore size is small, the inhomogeneity of the material does not adversely impact its transparency.

U.S. Pat. No. 6,420,647 to Ji describes a textured surface on a silicon solar cell made by applying a texturing layer comprising a SiO₂ film mixed with texturing particles having diameters on the order of 1-2 μm. The SiO₂ film is described as being thinner than the average diameter of the texturing particles. Ji describes that the texturing layer is placed on the back side of the substrate support glass and the silicon (photovoltaic) layer is applied on top of the texturing layer; i.e., the texturing layer is between the glass substrate and the photovoltaic layer. Ji also describes optionally using an antireflection coating in addition to the textured surface, placed in between the texturing layer and the silicon layer. The antireflection coating on top of the texturing layer would necessarily have an index of refraction higher than that of the glass substrate and the texturing layer, since silicon has a higher index of refraction. Ji discloses nothing with respect to the front (air) side of the glass substrate or with respect to antireflection layers operable at the air-glass interface.

U.S. Patent Application Publication No. 2011/0108101 to Sharma describes the use of an antireflection coating comprising sol-gel with colloidal silica having particle sizes of 10-110 nm coated onto a glass substrate. Sharma does not teach any particular relationship between particle size and coating thickness, but exemplifies coatings where the coating thickness is always greater than the particle size. The particle size is also described as providing a yellow color to the antireflection coating (the coating exhibits a b* value of 0.8 or greater).

### SUMMARY OF THE INVENTION

Light trapping and antireflection coatings are described, together with methods for preparing the coatings. An exemplary method comprises forming a light trapping coating on a substrate and a conformal antireflection coating on the light trapping coating. The light trapping coating comprises particles embedded in a support matrix having a thickness between about one third and two thirds of the mean particle size. The mean particle size is between about 10 μm and about 500 μm. The index of refraction of the particles and support matrix is substantially the same as the index of refraction of the substrate at wavelengths of interest. The index of refraction of the conformal antireflection coating is approximately equal the square root of the index of refraction of the substrate.

The light trapping coating can be formed by first applying a matrix precursor coating to the substrate, applying particles to the matrix precursor coating, and then curing the matrix precursor coating. Alternatively, the particles can be applied first and the matrix precursor coating applied thereafter. In some embodiments, the particles are suspended in a matrix precursor solution, then the matrix precursor solution and suspended particles are applied together to the substrate, and the matrix precursor solution is cured. The support matrix can be a xerogel or a polymer.

The matrix precursor solution can be applied to the substrate using one or more methods such as dip-coating, spin coating, spray coating, roll coating, slot die coating, meniscus coating, capillary coating, wire rod coating, doctor blade coating, or curtain coating. In some embodiments, the matrix precursor solution is applied to a heated substrate using a curtain coater. An exemplary matrix precursor solution comprises a sol-gel precursor such as a silane, solvent such as water, a non-aqueous solvent such as an alcohol, or mixtures thereof, and an acid or base catalyst. The heating is sufficient to convert the sol-gel precursor to a xerogel having embedded particles.

In some embodiments, the applying and heating step can be performed concurrently. In particular, the heating can be performed by preheating the substrate to a temperature of at least 400° C. before the matrix precursor solution is applied to the substrate. For example, in some embodiments, the substrate is float glass at a temperature of less than 700° C. when the coating is applied. The matrix precursor is heated by contact with the hot float glass and no additional heating is required, though the matrix precursor or substrate can optionally be further heated. In some embodiments, the matrix precursor solution is applied and the substrate and matrix precursor solution are heated together.

The conformal antireflection coating can have a thickness between about 100 nm and about 200 nm. In some embodiments, the conformal antireflection coating can have a thickness between about 120 nm and about 160 nm. The conformal antireflection coating can be formed by applying a sol-gel precursor solution, and curing the sol-gel precursor solution to form a xerogel. The sol-gel precursor solution can be applied to the substrate using one or more methods such as dip-coating, spin coating, spray coating, roll coating, slot die coating, meniscus coating, capillary coating, wire rod coating, doctor blade coating, or curtain coating. An exemplary precursor solution comprises a sol-gel precursor such as a silane, solvent such as water, a non-aqueous solvent such as an alcohol, or mixtures thereof, and an acid or base catalyst. In some embodiments, the sol-gel precursor solution includes a porogen for preparing a porous coating, providing a refractive index lower than that of the light trapping coating. The heating is sufficient to convert the sol-gel precursor to an inorganic monolith. For example, the heating can be to a temperature of from about 400° C. to about 700° C.

In some embodiments, a hydrophobic coating can be applied on the conformal antireflection coating. In some embodiments, an additive can be added to the sol-gel precursor solution to form a hydrophobic coating on the conformal antireflection coating. A silane-based hydrophobic surfactant can be a useful additive for providing a hydrophobic surface on the conformal antireflection coating. An additional heating step can be performed to promote covalent attachment of the hydrophobic coating to the conformal antireflection coating.

In some embodiments, the light trapping coating and the conformal antireflection coating can be cured together after precursors for both coatings have been applied. In some embodiments, the substrate is at a temperature of between about 400° C. and about 700° C. when the matrix precursor solution is applied to the substrate, and no additional heat is needed to cure the coating. Similarly, the conformal antireflection coating can be applied to a hot substrate having a light trapping coating disposed thereon.

Articles can be made incorporating a light trapping and conformal antireflection coating formed as disclosed above. The article can include a hydrophobic coating, or the conformal antireflection coating can contain an additive such that the cured coating has a hydrophobic surface. An exemplary article can be float glass. In some embodiments, the light trapping and conformal antireflection coating is disposed on only one side of the float glass. In some embodiments, the uncoated side is textured. In some embodiments, the article is part of a solar cell assembly.

A light trapping and conformal antireflection coating on a substrate is disclosed comprising a light trapping coating on a substrate and a conformal antireflection coating on the light trapping coating. The light trapping coating contains particles having a mean particle size between about 10 μm and about 500 μm embedded in a support matrix having a thickness between about one third and about two thirds of the mean particle size. The index of refraction of the particles and support matrix is substantially the same as the index of refraction of the substrate at wavelengths of interest. The index of refraction of the antireflection coating is approximately equal the square root of the index of refraction of the substrate.

### BRIEF DESCRIPTION OF THE DRAWINGS

FIG. 1 illustrates a light trapping layer with a conformal antireflection coating on a substrate.

FIG. 2 shows a flow diagram for forming a light trapping and antireflection coating according to an embodiment of the present invention.

### DETAILED DESCRIPTION

Before the present invention is described in detail, it is to be understood that unless otherwise indicated this invention is not limited to specific coating compositions or specific substrate materials. Exemplary embodiments will be described for selected sol-gel coatings on soda-lime glass, but other coating formulations and other types of glasses and transparent substrates can also be used. It is also to be understood that the terminology used herein is for the purpose of describing particular embodiments only and is not intended to limit the scope of the present invention.

It must be noted that as used herein and in the claims, the singular forms “a,” “and” and “the” include plural referents unless the context clearly dictates otherwise. Thus, for example, reference to “a solvent” includes two or more solvents, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. Where the modifier “about” or “approximately” is used, the stated quantity can vary by up to 10%. Where the modifier “substantially” is used, the two quantities may vary from each other by no more than 0.5%.

### Definitions:

The term “conformal” as used herein refers to the property of having an equal thickness at all points, regardless of texture exhibited by the underlying structure. The term conformal encompasses coatings that are fully conformal as well as coatings that are not fully conformal but instead exhibit thickness variations of less than about 10%.

The term “curing” as used herein refers to a treatment (generally with heat) that induces cross-linking and polymerization between Si atoms in sol-gels or cross-linking and polymerization between organic monomers to form organic polymers such as acrylic polymers.

The term “porosity” as used herein refers to a measure of the void spaces in a material, and may be expressed as a fraction, the “pore fraction” of the volume of voids over the total volume. Porosity is typically expressed as a number between 0 and 1, or as a percentage between 0 to 100%.

The term “porogen” as used herein refers to a constituent of the coating precursor solution that assists or enhances pore formation such that the cured coating is porous.

The term “sol-gel process” as used herein refers to a process where a wet formulation (the “sol”) is dried to form a gel coating comprised of solid network containing a liquid phase comprised primarily of solvent species, water and catalyst. The gel coating is then heat treated to remove the liquid phase and leave a strongly crosslinked solid material, which may be porous. The sol-gel process is valuable for the development of coatings because it is easy to implement and provides films of generally uniform composition and thickness.

The term “surfactant” as used herein refers to a compound that lowers the surface tension of a liquid and contains both hydrophobic groups and hydrophilic groups. Thus the surfactant contains both a water insoluble component and a water soluble component.

The term “silane surfactant” refers to a compound having a hydrophilic silane moiety which can react with silanol residues on glass or cured sol-gel surfaces, and having a hydrophobic moiety such as an alkyl. The silane surfactant can be used in a surface modification for reducing soiling on glass surfaces.

The term “total ash content” as used herein refers to the amount of inorganic components remaining after combustion of the organic matter in the sol formulation by subjecting the sol formulation to high temperatures. Exemplary inorganic materials remaining after combustion of the organic matter for a sol formulation described herein typically include silica from particles and silica from binder. However, other inorganic materials, for example, fluorine, may also be present in the total ash content after combustion. The “total ash content” is typically obtained by the following method:
1. Exposing a known quantity of a sol formulation to high temperatures greater than 600° C. to combust the organic matter.
2. Weighing the leftover inorganic material (referred to as “ash”).
   The total ash content is calculated from the following formula: total ash content (wt. %) of the sol formulation=(Weight of ash (g)/original weight of the sol formulation (g))×100.

The term “xerogel” as used herein refers to the solid network formed from a sol-gel process which remains after solvents and other swelling agents have been removed.

Embodiments of the present invention provide textured surfaces on substrates using light trapping coatings. Also provided are conformal antireflection coatings disposed on the textured surfaces. The angle of light incident on the surface of the substrate can vary over the course of time. For example, for solar collectors, as the sun traverses the sky, the incident angle changes. The light textured surface is able to collect a larger fraction of the incident light integrated over time, because some portion of the surface is always approximately oriented toward the incident light.

In some embodiments, the textured surface provided by a light trapping coating comprising particles having a mean particle size between about 10 μm and about 500 μm embedded in a support matrix having a thickness between about one third and about two thirds of the mean particle size. The index of refraction of the particles and support matrix can be substantially the same as the index of refraction of the substrate at wavelengths of interest. Generally the index of refraction of the particles and support matrix differs from the index of refraction of the substrate at wavelengths of interest by an amount that does not cause significant light scattering. In some embodiments, the index of refraction of the particles and the support matrix are within ±0.01 of the index of refraction of the substrate.

To further enhance light collection, an antireflection coating is provided on the textured surface. The antireflection coating can be conformal and between 100 and 200 nm thick. In some embodiments, the conformal antireflection coating can have a thickness between about 120 nm and about 160 nm. The index of refraction of the antireflection coating is less than the index of refraction of the substrate and the light trapping coating. In some embodiments, the index of refraction of the antireflection coating is approximately equal the square root of the index of refraction of the substrate.

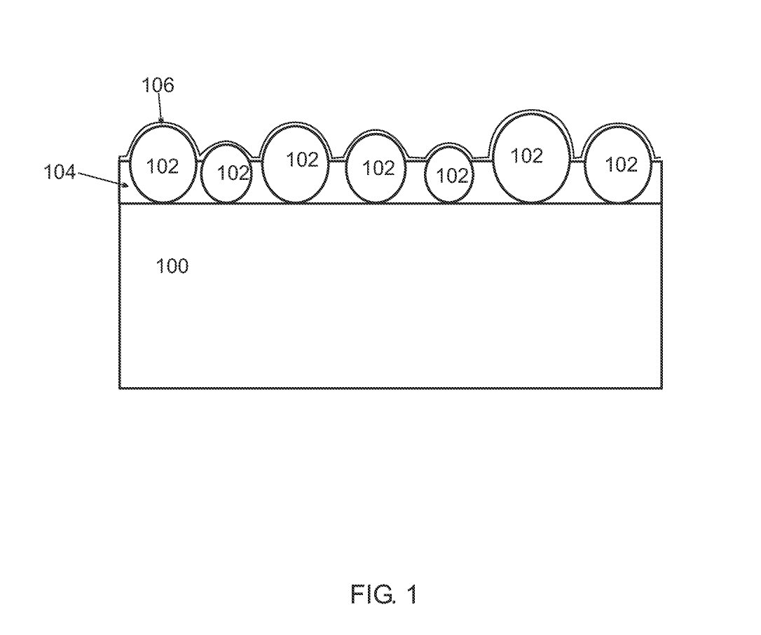

The light trapping and conformal antireflection coating is illustrated schematically in FIG. 1, where a substrate 100 is shown having a light trapping and antireflection coating. Particles 102 embedded in a support matrix 104 together form the light trapping coating, and provide a textured surface to the substrate. Particles 102 can have a range of sizes. The thickness of the support matrix 104 is between about one third and about two thirds of the mean diameter of particles 102. A conformal antireflection coating 106 is shown on the light trapping coating. The conformal antireflection coating 106 has a smaller index of refraction than the index of refraction of the particles and support matrix. Conformal antireflection coating 106 has an index of refraction intermediate between that of the media on either side of a surface (air on one side, substrate on the other in the illustrated example) and exhibits less light reflection and more light transmittance than a surface without such a coating. For a single-layer coating such as the conformal antireflection coating 106, the least light reflection generally occurs for a coating thickness of about one quarter of the incident wavelength and may vary over a range.

The optimum index of refraction for a single layer coating is generally the square root of the product of the indices of refraction on either side of the surface. For an air-substrate interface, this optimum index of refraction is equal to the square root of the substrate index of refraction, since the index of refraction of air is 1.0. For visible light use, the thickness is preferably about 120-160 nm which is about a quarter wavelength. The refractive index of the conformal antireflection coating is typically between 1.15 and 1.45, or between 1.18 and 1.30. In some embodiments, the refractive index of the conformal antireflection coating is between 1.20 and 1.25 for a non-graded index quarter wave thickness antireflection coating. For example, typical architectural glass substrates have an index of refraction of about 1.5, and good antireflection performance can be obtained using antireflection coatings with an index of refraction of about 1.22 and a thickness of 100-200 nm.

Articles can be made incorporating a light trapping and conformal antireflection coating formed as described below. An exemplary article can be float glass. In some embodiments, the light trapping and conformal antireflection coating is disposed on only one side of the float glass. In some embodiments, the uncoated side is textured. In some embodiments, the article is part of a solar cell assembly. For example, the article can be float glass which functions as a protective window through which the incident light reaches the light sensitive solar absorber. In embodiments where the solar absorber is a thin film device, the solar absorber can be formed on the float glass. In some embodiments, the light trapping and conformal antireflection coating can be formed on a nontransparent substrate to form a matte texture anti-soiling coating.

The article can further include a hydrophobic coating. In some embodiments, the conformal antireflection coating contains an additive such that the cured coating has a hydrophobic surface. In some embodiments, a hydrophobic coating is placed on top of the conformal antireflection coating. The hydrophobic coating can comprise any materials that confer anti-soiling behavior, such as fluoropolymers, alkylsilanes, fluoroalkylsilanes, and polydisilazanes.

The hydrophobic coating can be applied using both wet and dry deposition methods. Wet deposition methods include dip-coating, spin coating, spray coating, roll coating, slot die coating, meniscus coating, capillary coating, wire rod coating, doctor blade coating, or curtain coating. Dry deposition methods include, for example, plasma-deposition (reactive plasma, plasma polymerization) or CVD.

### Substrates

Any suitable transparent material can be used as a substrate. Glasses, e.g. low-iron glass, borosilicate glass, flexible glass, and crystalline oxides, as well as optical plastics such as polymethylmethacrylate (PMMA or ACRYLIC®), polystyrene, polycarbonate, or polyolefin, can all be used. Another example are transparent, UV-resistant, moisture-barrier-coated plastics as developed for the flexible thin film solar market, and display market. Typically the choice is made based on cost and physical properties such as durability and lifetime for the intended use, as well as optical properties such as transparency (extinction coefficient) and index of refraction at wavelengths of interest.

In some embodiments, the substrate is not transparent, and the light trapping and antireflection coating is applied to provide a surface having a matte texture and anti-soiling coating.

### Particles

The light trapping capabilities of the coating are provided by the surface texture. The surface texture can be generated by adding particles to the coating. The particles generally are of a size (average diameter) larger than about 10 μm, and can vary between about 10 μm and about 500 μm. The particle shape can be spherical, semi-spherical, or ellipsoidal; the shape can also be irregular (ground in a mill) or shaped like a regular or irregular polyhedron such as a pyramid or tetrahedron. The particles can be solid or porous, so long as the cured coating provides an index of refraction which is substantially the same as the index of refraction of the substrate.

In some embodiments, the particles and support matrix are formed using a sol-gel process, and can be made from the same or similar sol-gel precursor solutions as the support matrix coating. In some embodiments, the particles are made from the same material as the substrate. In some embodiments, the particles are made from a material different from the support matrix and the substrate, but having substantially the same index of refraction as the support matrix and the substrate. The particles can be formed by grinding in a suitable mill, cooling from sprayed droplets, molding, or other suitable process to form particles having the target size distribution.

In some embodiments, the particles can be generated in situ in a support matrix solution. One exemplary sol-gel composition for in situ generation of particles includes a silane precursor (e.g., tetraethylorthosilane, TEOS), water, a base catalyst (e.g., trimethylammonium hydride, TMAH), and an alcohol solvent (e.g. n-propyl alcohol, NPA). The components can be mixed for twenty-four hours at room or elevated (˜60° C.) temperatures. The particles form from the condensation and polymerization of the TEOS monomers.

In some embodiments, the particles and support matrix are highly transparent, having a negligible extinction coefficient at wavelengths of interest. The matrix and particles can be made from any material that can be conveniently applied to the substrate and has a desired index of refraction and extinction coefficient at wavelengths of interest (such as visible wavelengths or visible and near-infrared wavelengths). Example materials include dense xerogels, glass beads, and transparent organic polymers such as the optical plastics described for substrate materials.

### Sol-Gel Precursor Solutions

Sol-gel precursors include metal and metalloid compounds having hydrolyzable ligands that can undergo a sol-gel reaction and form sol-gels. Suitable hydrolyzable ligands include hydroxyl, alkoxy, halo, amino, or acylamino, without limitation. The most common metal oxide participating in the sol-gel reaction is silica, though other metals and metalloids are can also be useful in small quantities, such as zirconia, vanadia, titania, niobium oxide, tantalum oxide, tungsten oxide, tin oxide, hafnium oxide and alumina, or mixtures or composites thereof, having reactive metal oxides, halides, amines, etc., capable of reacting to form a sol-gel. Additional metal atoms that can be incorporated into the sol-gel precursors include magnesium, molybdenum, cobalt, nickel, gallium, beryllium, yttrium, lanthanum, tin, lead, and boron, without limitation.

In some embodiments, the sol-gel precursors include, but are not limited to, silicon alkoxides, such as tetramethylorthosilane (TMOS), tetraethylorthosilane (TEOS), fluoroalkoxysilane, or chloroalkoxysilane, germanium alkoxides (such as tetraethylorthogermanium (TEOG)), vanadium alkoxides, aluminum alkoxides, zirconium alkoxides, and titanium alkoxides. Similarly, halides, amines, and acyloxy derivatives can also be used in the sol-gel reaction. In some embodiments, the sol-gel precursor is an alkoxide of silicon, germanium, aluminum, titanium, zirconium, vanadium, or hafnium, or mixtures thereof. Some commercially available metal alkoxides include tetraethoxysilane, tetraethyl orthotitanate and tetra-n-propyl zirconate. In some embodiments, the sol-gel precursor is a silane, such as TEOS or TMOS.

The sol-gel precursor solution can include an acid or base catalyst for controlling the rates of hydrolysis and condensation. The acid or base catalyst can be an inorganic or organic acid or base catalyst. Exemplary acid catalysts include hydrochloric acid (HCl), nitric acid (HNO₃), sulfuric acid (H₂SO₄), acetic acid (CH₃COOH) and combinations thereof. Exemplary base catalysts include ammonium hydroxide and tetramethylammonium hydroxide (TMAH). The acid catalyst concentration can be from 0.001 to 10 times the concentration of the sol-gel precursor by mole fraction. The base catalyst concentration can be 0.001 to 10 times the concentration of the sol-gel precursor by mole fraction. The amount of acid catalyst concentration can be from 0.001 to 0.1 wt. % of the total weight of the sol-gel composition. The amount of base catalyst concentration can be from 0.001 to 0.1 wt. % of the total weight of the sol-gel composition.

The sol-gel precursor solution further includes a solvent system. The solvent system can include a non-polar solvent, a polar aprotic solvent, a polar protic solvent, and combinations thereof. Selection of the solvent system can be used to influence the timing of the sol-gel transition. Exemplary solvents include alcohols, for example, n-butanol, isopropanol, n-propanol (NPA), ethanol, methanol, and other well known alcohols. The amount of solvent can be from 80 to 95 wt. % of the total weight of the sol-gel composition. The solvent system can further include water. The amount of water can be from 0.001 to 0.1 wt. % of the total weight of the sol-gel composition. In certain embodiments, water may be present in 0.5 to 10 times the stoichiometric amount needed to hydrolyze the silicon containing precursor molecules.

In some embodiments, the antireflection coating can further comprise a hydrophobic coating. In these embodiments, the sol-gel precursor can comprise an additive such that the coating has a hydrophobic surface. For example, the sol-gel precursor can comprise a fluorinated silane (e.g., triethoxyfluorosilane) or silane surfactant, such as an alkylsilane, fluoroalkyl silane, or the like. In these embodiments, the sol-gel is treated at temperatures that do not destroy the desired organic functionalities, or the curing is performed in the absence of an oxidizing atmosphere. In some embodiments, the hydrophobic coating can be added after the coating is formed. For example, the antireflection coating can be treated with a silane surfactant. In some embodiments, the hydrophobic coating (e.g., a silane surfactant) can be applied to the antireflection coating, and both coatings can be heated together to cure the coatings. In some embodiments, the hydrophobic coating can be applied to the antireflection coating after the antireflection coating is heated, and the coating can be heated again to cure the hydrophobic coating.

### Porogens

Porogens can be included in the coating precursor solution to introduce porosity when using the sol-gel process. The choice of porogen is not particularly limiting, so long as it enhances the porosity or provides a target porosity to the cured sol-gel coating. Porogens include surfactants, polymers, or water immiscible solvents such as xylene, fluoroalkanes, or hydrophobic silicone fluids. Organic nanocrystals, dendrimers, organic nanoparticles, etc. at 1-5% by weight can also be used as porogens.

The porogen can be a surfactant selected from non-ionic surfactants, cationic surfactants, anionic surfactants, or combinations thereof. Exemplary non-ionic surfactants include non-ionic surfactants with linear hydrocarbon chains and nonionic surfactants with hydrophobic trisiloxane groups. The porogen can be a trisiloxane surfactant. Exemplary porogens can be selected from the group comprising: polyoxyethylene stearyl ether, benzoalkoniumchloride (BAC), cetyltrimethylammoniumbromide (CTAB), 3-glycidoxypropyltrimethoxysilane (Glymo), polyethyleneglycol (PEG), ammonium lauryl sulfate (ALS), dodecyltrimethylammoniumchloride (DTAC), polyalkyleneoxide modified hepta-methyltrisiloxane, and combinations thereof. Some exemplary porogens include cetyltrimethylammonium bromide (CTAB) at 2% by weight, Ammonium Lauryl Sulfate (ALS) at 1% by weight, or Sylwet 1-77 at 3% by weight. Exemplary porogens are commercially available from Momentive Performance Materials under the tradename SILWET® surfactant and from SIGMA ALDRICH® under the tradename BRIJ® surfactant. Suitable commercially available products of that type include SILWET L-77 surfactant and BRIJ 78 surfactant. The porogen can comprise at least 0.1 wt. %, 0.5 wt. %, 1 wt. %, or 3 wt. % of the total weight of the sol-gel composition. The porogen can comprise at least 0.5 wt. %, 1 wt. %, 3 wt. % or 5 wt. % of the total weight of the sol-gel composition. The porogen can be present in the sol-gel composition in an amount between about 0.1 wt. % and about 5 wt. % of the total weight of the sol-gel composition. In some embodiments, the porogen is a surfactant such as Sylwet 1-77 and is added to the coating precursor solution at a wt. % from 0.001 to 10%.

Polymers can also be utilized as porogens. For example, dissolved organic polymers, such as polystyrene sulfonic acid, polyacrylic acid, polyallylamine, polyethylene-imine, polyethylene oxide, or polyvinyl pyrrolidone, can be included to introduce pores during hydrolysis and polymerization of the sol-gel precursors, as described in U.S. Pat. No. 5,009,688 to Nakanishi. Preparation of the sol-gel in the presence of the phase separated volumes provides a sol-gel possessing macropores and/or large mesopores, which provide greater porosity to the sol-gel.

In some embodiments, the porogen can be a hydrophilic polymer. The amount and hydrophilicity of the hydrophilic polymer in the sol-gel forming solution affects the pore volume and size of macropores formed, and generally, no particular molecular weight range is required, although a molecular weight between about 1,000 to about 1,000,000 g/mole is preferred. The porogen can be selected from, for example, polyethylene glycol (PEG), sodium polystyrene sulfonate, polyacrylate, polyallylamine, polyethyleneimine, poly(acrylamide), polyethylene oxide, polyvinylpyrrolidone, poly(acrylic acid), and can also include polymers of amino acids, and polysaccharides such as cellulose ethers or esters, such as cellulose acetate, or the like. In some embodiments, the porogen is a polymer such as polyethylene glycol and is added to the coating precursor solution at a weight % of 0.001 to 5%.

The porogen can be an organic solvent so long as the porogen is phase separated from the sol-gel forming solution and forms micelles in the solution. The size of the micelles of porogen is related to the size of the pores formed. The porogen can be removed during drying or pyrolized during the curing process.

For preparation of antireflection coatings comprising porous organic polymers, porogens can also be utilized to confer porosity to the cured coating, whether the coating is formed by polymerization of one or more monomers or block copolymers or by removal of solvent from a dissolved polymer. Suitable porogens include solution constituents which remain phase separated, such that the cured coating forms with voids. When the porogen is removed by washing with a solvent in which the porogen is soluble or by evaporation, the void is filled with air, imparting a porous structure to the coating, and a reduced refractive index. The desired refractive index can be achieved by choice and concentration of porogen, along with the refractive index of the polymeric coating.

### Methods for Preparing Light Trapping and Antireflection Coatings

Methods are provided for preparing light trapping and antireflection coatings. The light trapping coating can be formed by applying a matrix precursor coating to the substrate, applying particles to the matrix precursor coating, and then curing the matrix precursor coating. In some embodiments, the particles can be applied first and the matrix precursor coating applied thereafter, followed by curing. For example, the particles can be applied to the substrate (e.g., by electrostatic deposition) followed by a second step to apply the first sol-gel precursor solution. In both cases, the sol-gel precursor solution and the particles are distributed on the substrate though applied separately. In some embodiments, particles are suspended in a matrix precursor solution, then the matrix precursor solution and suspended particles are applied together to the substrate, and the matrix precursor solution is cured.

In some embodiments, a plurality of light trapping coating layers are applied to a substrate, where the layers can comprise the same or different compositions. For example, a first matrix precursor solution having a first composition (with or without particles) can be applied to the substrate, followed by a second matrix precursor solution having a second composition (with or without particles), and the two coatings cured together. If the matrix precursor solutions do not contain particles, then particles can be applied to the coating before the coating layers are cured so that the particles are incorporated into the cured coating. The compositions of the plurality of light trapping coating layers can vary as desired. For example, variables include the sol-gel precursor to particle ratio, mean particle size, sol-gel precursor concentration, solvent, water, acid or base, and so forth.

The support matrix can be a xerogel or a polymer. Polymers include organic polymers, fluoropolymers, silicones and polysilazanes. Organic polymers include acrylates, methacrylates, epoxides, as well as hybrid silicone-organic polymers. Other colorless and transparent polymers, such as certain types of urethanes would also be suitable. Organic polymers will typically have a refractive index higher than glass, in the range of 1.53 to 1.58 in most cases.

In some embodiments, polymers are used “as is,” i.e., an organic polymer is dissolved in a solvent to form a polymer solution and applied to the substrate, particles are applied (or the polymer solution comprises particles), followed by removal of the solvent. In some embodiments, the polymer is formed by polymerization of one or more polymerizable organic monomers with particles to provide a cured matrix precursor coating having embedded particles. In some embodiments, the polymer is formed by polymerization of one or more polymerizable organic monomers, oligomers or polymers with particles to provide a cured matrix precursor coating having embedded particles. As described above, a plurality of matrix precursor coating layers can be applied if desired, and can comprise the same or different compositions.

The matrix precursor solution can be applied to the substrate using one or more methods such as dip-coating, spin coating, spray coating, roll coating, slot die coating, meniscus coating, capillary coating, wire rod coating, doctor blade coating, or curtain coating. In some embodiments, the matrix precursor solution is applied to a heated substrate using a curtain coater. An exemplary matrix precursor solution comprises a sol-gel precursor such as a silane, solvent such as water, a nonaqueous solvent, or mixtures thereof, and an acid or base catalyst. Typically, in order to match the index of refraction of the cured sol-gel to the substrate, a fully dense xerogel (i.e., without pores) is needed, and no porogen is added to the matrix precursor solution. The heating is sufficient to convert the sol-gel precursor to an inorganic monolith.

In some embodiments, the applying and heating step can be performed concurrently. In particular, the heating can be performed by preheating the substrate to a temperature of at least 400° C. before the matrix precursor solution is applied to the substrate. For example, in some embodiments, the substrate is float glass at a temperature of less than 700° C. when the coating is applied. The matrix precursor solution is heated by contact with the hot float glass and no additional heating is required, though the matrix precursor or substrate can optionally be further heated. In some embodiments, the matrix precursor solution is applied and the substrate and matrix precursor solution are heated together. In some embodiments, the coating can be selectively heated using methods such as IR laser annealing, UV RTP, or microwave processing.

In some embodiments, the conformal antireflection coating can be formed by applying a solution comprising one or more polymerizable monomers or oligomers, such as a sol-gel precursor solution, and curing the sol-gel precursor solution to form a xerogel. The sol-gel precursor solution can be applied to the light trapping coating on the substrate using one or more methods such as dip-coating, spin coating, spray coating, roll coating, slot die coating, meniscus coating, capillary coating, wire rod coating, doctor blade coating, curtain coating. An exemplary precursor solution comprises a sol-gel precursor such as a silane, solvent such as water, a nonaqueous solvent, or mixtures thereof, and an acid or base catalyst. In some embodiments, the sol-gel precursor solution includes a porogen for preparing a porous coating, providing a refractive index lower than that of the light trapping coating. The heating is sufficient to convert the sol-gel precursor to an inorganic monolith. For example, the heating can be to a temperature of at least 400° C.

In some embodiments, the conformal antireflection coating can be formed by applying a solution comprising one or more polymerizable organic monomers or oligomers, along with solvent, optional polymerization initiators and porogens to the light trapping coating on the substrate. In some embodiments, the conformal antireflection coating can be formed by applying a solution comprising one or more organic polymers, solvent and optional porogen. The solution constituents (e.g., polymer, monomers, solvent, porogen, etc.) can be chosen to achieve a desired porosity and/or refractive index and for chemical compatibility with the light trapping coating.

The conformal antireflection coating can have a thickness between about 100 nm and about 200 nm. In some embodiments, the conformal antireflection coating can have a thickness between about 120 nm and about 160 nm. The viscosity of the solution comprising polymerizable monomers (e.g., sol-gel precursor solution or organic monomers or oligomers) or polymer can be varied by choice of solvent or concentration in order to facilitate preparation of a conformal antireflection coating of desired thickness and according to the desired application method.

In some embodiments, an anti-soiling (hydrophobic) coating can be applied by depositing silane-based or other hydrophobic surfactants (e.g., bis(trimethylsilyl)amine, also known as hexamethyldisilazane or HMDS) from solution onto the cured porous coating at or near room temperature, followed by a soak step to allow the surfactants to cover the surface of the sol-gel coating. Subsequently, drying and curing at temperatures <200° C. allows for chemical bonding of the surfactants to the silica-based xerogel coating.

In some embodiments, the light trapping coating and the conformal antireflection coating can be cured together after precursor solutions for both coatings have been applied. In some embodiments, the substrate is at a temperature of between 400° C. and 700° C. when the matrix precursor solution with particles is applied to the substrate, and no additional heat is needed to cure the coating. Similarly, the conformal antireflection coating can be applied to the coating of matrix precursor solution and particles on a hot substrate.

An exemplary method comprises first forming a light trapping surface by providing a matrix precursor solution, applying the matrix precursor solution to a substrate, and heating the first matrix precursor solution on the substrate to form a first cured coating. The matrix precursor solution comprises a mixture comprising a sol-gel precursor solution and particles having a defined size distribution. The index of refraction of the particles and the first cured coating is substantially equal to the index of refraction of the substrate, and the mean of the defined particle size distribution is generally in the range of 10-500 μm. The substrate can comprise any transparent material, for example, glass. For a refractive index of 1.5 (for glass), the light trapping coating has a refractive index within ±0.01 of the index of refraction of the substrate, i.e., the refractive index of the coating is between about 1.49 and 1.51.

After the light trapping surface is formed, an antireflection coating can be applied. A second coating comprising a sol-gel precursor solution can be applied to the light trapping surface, and the solution can be heated to form a second cured coating.

### EXAMPLES

### Example 1

### Preparation of a Light Trapping and Antireflective Coating on a Glass Substrate

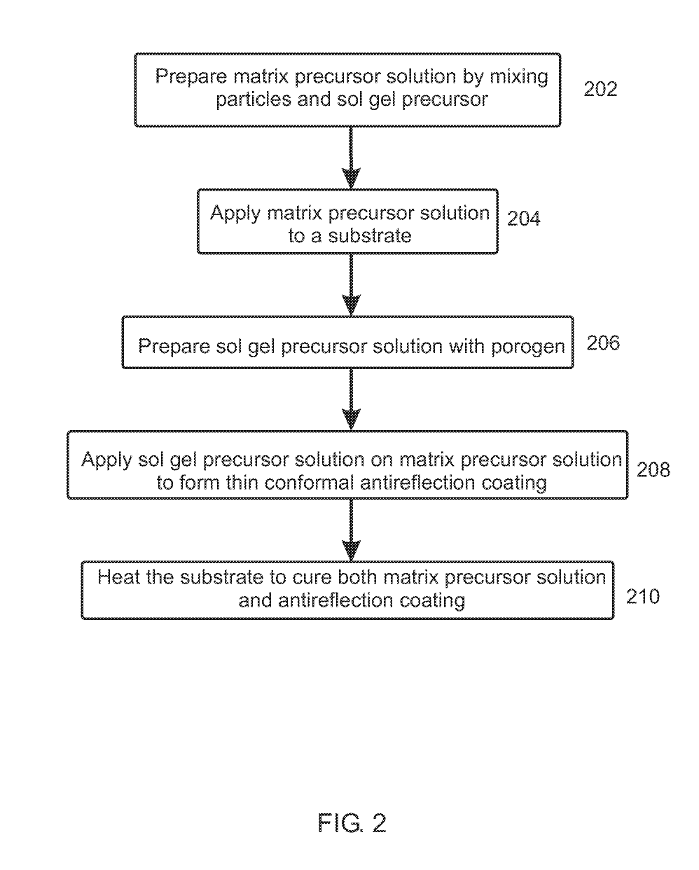

A light trapping and antireflective coating can be prepared on a glass substrate by the following method. An illustration of the method is shown in FIG. 2. A glass substrate having an index of refraction of 1.5 is cleaned in preparation for receiving the light trapping and antireflection coating precursor solution. A first coating precursor solution comprising a mixture of particles having a defined size distribution (e.g., mean of 50 μm, half-width of 20 μm) and a sol-gel precursor solution are mixed as shown in step 202 of FIG. 2. The particles are particles of silica. The sol-gel precursor solution is prepared using tetraethylorthosilane (TEOS) as the silane-based binder, n-propanol as the solvent, acetic acid as the catalyst, and water. The total ash content of the solution is 4% (based on equivalent weight of SiO₂ produced). The ratio of silane to particles is 50:50 by weight (ash content contribution). TEOS and particles are mixed with water (2 times the molar TEOS amount), acetic acid (5 times the molar TEOS amount), and n-propanol. The solution is mixed at room temperature and stirred for 24 hours at 60° C.

The first coating precursor solution is applied (step 204) to a glass substrate using a curtain coating method, and the glass substrate is heated in an oven at 400° C. for 1 hr to gel and remove solvent. The temperature of the oven is then increased to 600° C. for 1 hr to cure and calcine the first coating (the light trapping coating). The cured first coating is approximately 25 μm thick in regions between particles and approximately 50 μm thick where particles are present. After the coating is cured, the index of refraction of the coating and particles is substantially the same as the index of refraction of the glass substrate.

A second coating precursor solution without particles can then be applied (step 208). The second coating precursor solution comprises a second sol-gel precursor solution prepared (step 206) by similar methods to the first sol-gel precursor solution but including a porogen, such as cetyltrimethylammonium bromide (CTAB) at 2% by weight, Ammonium Lauryl Sulfate (ALS) at 1% by weight, or Sylwet 1-77 at 3% by weight. The second coating precursor solution is applied over the first cured coating, then cured to form a second (porous) coating having a thickness of about 140 nm and a refractive index of 1.22.

Optionally, the two curing processes can be combined into a single heat-curing process 210 as illustrated in FIG. 2. Through this simple process, a combined light trapping and antireflection coating can be applied.

### Example 2

### Preparation of a Light Trapping and Antireflective Coating on a Glass Substrate

A process is performed similar to that described in Example 1. The two coating precursor solutions are applied using a curtain coating method to float glass, while the glass is still at elevated temperature. The coating precursor solutions are applied to the float glass as it is removed from the oven and enters the cooling chamber on rollers, but before it has cooled below 600° C. The hot glass provides sufficient heat to the first coating solution to gel and cure the sol-gel precursor, resulting in a textured coating, effective for light trapping. Likewise, the second coating solution is cured by the heat to provide a conformal antireflection coating. Through this simple process, a combined light trapping and antireflection coating can be applied to float glass through an economical and efficient manufacturing process.

It will be understood that the descriptions of one or more embodiments of the present invention do not limit the various alternative, modified and equivalent embodiments which may be included within the spirit and scope of the present invention as defined by the appended claims. Furthermore, in the detailed description above, numerous specific details are set forth to provide an understanding of various embodiments of the present invention. However, one or more embodiments of the present invention may be practiced without these specific details. In other instances, well known methods, procedures, and components have not been described in detail so as not to unnecessarily obscure aspects of the present embodiments.

What is claimed is:

1. A method of forming a coating on a substrate, the method comprising
forming a first coating on the substrate; and
forming a second coating on the first coating;
wherein the first coating comprises particles having a mean particle size between 10 μm and 500 μm embedded in a support matrix having a thickness between one third and two thirds of the mean particle size;
wherein an index of refraction of the particles and support matrix is substantially the same as an index of refraction of the substrate at wavelengths of interest;
wherein an index of refraction of the second coating is approximately equal to the square root of the index of refraction of the substrate.

2. The method of claim 1, wherein the forming a first coating comprises
applying a matrix precursor solution to the substrate,
applying particles to the matrix precursor solution, and
curing the matrix precursor coating.

3. The method of claim 1, wherein the forming a first coating comprises
suspending the particles in a matrix precursor solution,
applying the matrix precursor solution and suspended particles to the substrate, and
curing the matrix precursor solution.

4. The method of claim 1, wherein the support matrix comprises a xerogel.

5. The method of claim 1, wherein the support matrix comprises a polymer.

6. The method of claim 1, wherein the forming a second coating comprises
applying a sol-gel precursor solution, and
curing the sol-gel precursor solution to form a xerogel.

7. The method of claim 1, wherein the second coating has a thickness between 100 nm and 200 nm.

8. The method of claim 7, wherein the second coating has a thickness between 120 nm and 160 nm.

9. The method of claim 1, further comprising curing the first coating and the second coating after both coatings have been formed.

10. The method of claim 1, further comprising applying a hydrophobic coating on the second coating.

11. The method of claim 3, wherein the substrate is at a temperature of between 400° C. and 700° C. when the matrix precursor solution is applied to the substrate.

12. The method of claim 6, wherein the sol-gel precursor solution comprises a porogen.

13. An article comprising a coating made by the method of claim 1.

14. The article of claim 13, further comprising a hydrophobic coating.

15. The article of claim 13, wherein the coating further comprises an additive such that the cured coating has a hydrophobic surface.

16. The article of claim 13, wherein the article comprises float glass.

17. The article of claim 16, wherein the coating is disposed on only one side of the float glass.

18. The article of claim 17, wherein the uncoated side of the float glass is textured.

19. The article of claim 13, wherein the article is a solar cell assembly.

20. A coating on a substrate comprising
a first coating formed on the substrate; and
a second coating formed on the first coating;
wherein the first coating comprises particles having a mean particle size between 10 μm and 500 μm embedded in a support matrix having a thickness between about one third and about two thirds of the mean particle size;
wherein an index of refraction of the particles and support matrix is substantially the same as an index of refraction of the substrate at wavelengths of interest;
wherein an index of refraction of the second coating is approximately equal the square root of the index of refraction of the substrate.
